(19) United States
(12) Patent Application Publication
(10) Pub. No.: US 2009/0007952 A1
(43) Pub. Date: Jan. 8, 2009

(54) Structure of Peltier Element or Seebeck Element and Its Manufacturing Method

(76) Inventors: Yoshiomi Kondoh, Gunma (JP); Naotaka Iwasawa, Gunma (JP)

Correspondence Address: FOLEY AND LARDNER LLP;SUITE 500, 3000 K STREET NW, WASHINGTON, DC, 20007, US

(21) Appl. No.: 11/664,937

(22) PCT Filed: Oct. 17, 2005
(86) PCT No.: PCT/JP05/19053

§ 371 Date: Apr. 9, 2007

(30) Foreign Application Priority Data
Oct. 18, 2004 (JP) 2004-303321

(51) Int. Cl. H01L 35/28; G03F 7/20

(52) U.S. Cl. 136/203; 430/312

(57) ABSTRACT

A Peltier or Seebeck element has first and second conductive members having different Seebeck coefficients. To decrease the heat conduction from one to the other end of each of the conductive members, the cross-section area at the intermediate part in the length direction is smaller than those at both ends parts. In place of the decrease of the cross-section, the shape of the cross-section of the intermediate part of each of the conductive members may be changed by dividing the intermediate part into pieces, or amorphous silicon or the like having a heat conductivity lower than those of the materials of both end parts may be used for the material of the intermediate part. In such a way, a high-performance Peltier/Seebeck element such that the difference between the temperature of the heated portion of the Peltier/Seebeck element and the opposite portion can be kept to a predetermined temperature difference for a long time and its manufacturing method are provided.

### TECHNICAL FIELD

This invention relates to a structure of an element to enhance a function of a Peltier element or a Seebeck element used in a thermoelectric conversion system or a thermoelectric conversion apparatus which is arranged to convert thermal energy in all portions, spaces and regions that a temperature is increased, such as buildings and objects that heat from outside due to various electronics, combustion apparatuses, its related equipments, sun light, geotherm and so on is affected, and its manufacturing process.

### BACKGROUND ART

Energy in natural world is used irreversibly, becomes thermal energy at last, and discharged to the natural world. In general, the thermal energy discharged to the natural world is not used for the human, and conversely may affect the natural world adversely. Therefore, for eliminating and removing this thermal energy, a forcible air cooling and a forcible water cooling are performed by using energy and electric energy by further new heat engines.

For example, in a case in which buildings and objects affected by the irradiation of the sunlight, the geotherm and so on, or its circumferences becomes high temperature, in order to eliminate and remove the thermal energy in the high temperature portion, the forcible air cooling and the forcible water cooling are performed by the energy and the electric energy by the further new heat engines. It is problematic that use efficiency of the thermal energy is decreased with increase of the energy used for the elimination and the removal of the thermal energy.

Currently, investigation to reuses these thermal energy positively to improve energy conservation, and to decrease the effect on environment is started. Effort to develop practical application is being performed in various quarters. However, in fact, the inexhaustible thermal energy which is final form of the energy, and which exists in the natural world can not reuse positively, without input of the new energy, to decrease the adverse effect on the environment.

Conversion from the thermal energy to a directly usable form such as the electric energy can be attained by physics phenomenon known as Peltier effect or Seebeck effect. That is, radiating or absorbing heat is produced other than Joule heat when current flows through conductors of two different kinds which are connected and held at a uniform temperature. This effect is the phenomenon first discovered by J. C. A. Peltier in 1834, and called Peltier effect. Moreover, when copper wires of two different kinds are connected, the two contact points are held at different temperatures T1 and T2, and one of the conductive wires is cut, then an electromotive force is produced between the cut ends. This electromotive force generated between the two ends is called thermal electromotive force, and this phenomenon is called Seebeck effect in honor of the discover.

The development of a thermoelectric converter element (Seebeck element) utilizing the Seebeck effect is attracting attention as substitute energy for fossil fuel and atomic power. The thermo-electromotive force of the Seebeck element is dependent on the temperatures of the two contact points, and moreover on the materials of two conductor wires, and a derivative value obtained by dividing the thermo electromotive force by a temperature variation is called a Seebeck coefficient. The thermoelectric conversion element is formed by contacting two conductors (or semiconductors) different in the Seebeck coefficient. Due to difference in the number of free electrons in the two conductors, the electrons move between the two conductors, resulting in a potential difference between the two conductors. If heat energy is applied to one contact point, and the movement of the free electrons is activated at the contact point, but the free electron movement is not activated at the other contact point being provided with no heat energy. This temperature difference between the contact points, that is the difference in the activation of free electrons, causes conversion from heat energy to electric energy. This effect is generally referred to as thermoelectric effect.

In general, the above-described Seebeck element is formed of an integral element of a heat part (high temperature side) and a cool part (low temperature side). Moreover, the thermoelectric effect element utilizing the Peltier effect (hereinafter, referred to a Peltier element) is formed of an integral element of a heat absorption part and a heat generation part. That is, in the Seebeck element, the heat part and the cool part interfere thermally with each other. In the Peltier element, the heat absorption part and the heat generation part interfere thermally with each other. Accordingly, these Seebeck effect and Peltier effect are decreased with the passage of the time. For preventing this, currently, heat release is performed by the forcible air cooling and the forcible water cooling by using the energy and the thermal energy by the heat engine for the elimination and the removal of thermal energy in the high temperature part.

Accordingly, in a case in which extensive energy conversion provision are built up by using the above-described Peltier element and Seebeck element, new heat engines are needed in installation location of that provision and so on, and it is unreal for this physical limitation.

The inventor(s) (applicant) of the present invention has invested and proposed a thermoelectric conversion apparatus which does not need the new heat engine and the forcible air cooling and the forcible water cooling by the electric energy, and an energy conversion system utilizing this (cf. patent document 1). Moreover, the inventor proposed, as patent application 2004-194596, a Peltier Seebeck element chip that a plurality of the Peltier elements or the Seebeck elements are provided on an integrated substrate, and production method therefor.

Patent document: Japanese Patent Application Publication No. 2003-92433

Patent document: Japanese Patent Application No. 2004-194596

However, in a case in which the Peltier Seebeck element described in the patent document 1 or the integrated Peltier Seebeck element chip described in the patent document 2 are assembled in circuit system, it is necessary to utilize the Seebeck element or the Peltier element with the conventional shape as shown in FIG. 44. That is, as shown in FIG. 44, one end (T1: high temperature side) of a first conductive member (for example, n-type semiconductor) 101 and one end (T1 high temperature side) of a second conductive member (for example, p-type semiconductor) 102 which have different Seebeck coefficient are joined by a joining member 103 made of a metal such as a copper, by an ohmic contact. The other end (T2: low temperature side) of first conductive member 101 and the other end (T2: low temperature side) of second conductive member 102 are joined through joining members 104 and 105 also made of the metal such as the copper, to the other end (T2: low temperature side) of the second and the first conductive member of another Seebeck elements (not shown).

In a conventional pai type element as shown in FIG. 44, the thermal conductivity of the semiconductor forming the first and second conductive members 101 and 102 is a relatively large value of one-two hundredth of the copper. Accordingly, it is difficult to keep, for a long time, a state that the temperature difference ΔT between the temperature (T1) of the high temperature side and the temperature (T2) of the low temperature side is a large value.

Accordingly, as shown in FIG. 44, in the case in which the conventional pai type Seebeck element or the Peltier element is assembled, it is problematic that the flow of the thermal energy from the high temperature side to the low temperature side of each element by the heat conduction can not be ignored. Therefore, in a case in which the heat transfer is performed by the pai type Peltier effect, the temperature of the low temperature side is increased and becomes higher than the temperature of the circumference that takes the heat, for the heat conduction from the high temperature side to the low temperature side, even when the temperature difference between the high temperature side and the low temperature side is caused by the function of the heat generation and the heat absorption by the Peltier effect and the temperature of the low temperature side is decreased than the temperature of the circumference. Consequently, it is not possible to take the heat from the circumference, and it is problematic that the heat transfer can not be performed. It is problematic that for preventing this, in general, metal heat absorbing member with a large thermal capacity is attached to the high temperature side, and the thermal energy must be forcibly discharged from the high temperature side to the outside by providing a small electric fan by using a new electric energy.

Moreover, in a case of the thermal conversion element which converts the thermal energy to the electric energy by the Seebeck effect by using the temperature difference, it is problematic that the temperature of the low temperature side is increased by the heat conduction from the high temperature side to the low temperature side of the Seebeck element, and that the Seebeck electromotive force is decreased and the conversion efficiency from the thermal energy to the electric energy is decreased. It is disadvantageous that, for preventing this, the heat release must be performed by attaching, to the low temperature side, the forcible air cooling system and the forcible water cooling system which use the energy and the electric energy by the new heat engine.

In this way, in the case of the thermoelectric conversion element or the thermal transfer element which are assembled with the Seebeck element or the Peltier element with the conventional shape, the conversion efficiency of the entire apparatus from the thermal energy to the electric energy, that is, the use efficiency of the thermal energy is constrained to a low value by the flow of the thermal energy from the high temperature side to the low temperature side of each element by the heat conduction, and the improvement of the use efficiency of the thermal energy becomes large technical problem.

### DISCLOSURE OF INVENTION

The present invention has been devised to solve the above-mentioned problem. It is an object of the present invention to provide a Peltier element or a Seebeck element with a new structure and its manufacturing method. Especially, shapes (or materials) of a first conductive member and a second conductive member of used elements are varied to decrease movement of thermal energy from a high temperature side to a low temperature side by a heat conduction, to increase use efficiency of the thermal energy, and to decrease manufacturing cost of the element.

More specifically, a structure of a Peltier element or a Seebeck element comprises: a first conductive member and a second conductive member forming the Peltier element or the Seebeck element, having different Seebeck coefficients, and each including an intermediate part in a longitudinal direction which has a thermal conductivity smaller than thermal conductivities of both end parts.

According to another aspect of the present invention, the intermediate parts of the first and second conductive members in the longitudinal direction which is other than both end parts have cross sections smaller than cross sections of the both end parts.

Moreover, according to still another aspect of the present invention, the intermediate parts of the first conductive member and the second conductive member in the longitudinal direction which are other than the both end parts is formed from a material which has a thermal conductivity smaller than a thermal conductivity of a material of the both end parts.

Moreover, according to still another aspect of the present invention, the intermediate parts of the first conductive member and the second conductive member in the longitudinal direction which are other than the both end parts are divided into a plurality of parts to form a constriction in a sectional shape.

Moreover, according to still another aspect of the present invention, a manufacturing process for a Peltier element or a Seebeck element having different Seebeck coefficients, and each having an intermediate part in a longitudinal direction which has a thermal conductivity smaller than thermal conductivities of both end parts, the manufacturing process comprises: (1) a step of forming a first region pattern by forming a cast, and by forming a pretreatment pattern by using a photo mask method to form a first region which is a region of one of the both end parts of each of the first conductive member and the second conductive member forming the Peltier element or the Seebeck element; (2) a step of forming a second region pattern by forming a cast, and by forming a pretreatment pattern by using a photo mask method to form a second region which is a region of one of the intermediate part of each of the first conductive member and the second conductive member forming the Peltier element or the Seebeck element; (3) a step of forming a third region pattern by forming a cast, and by forming a pretreatment pattern by using a photo mask method to form a third region which is a region of the other of the both end parts of each of the first conductive member and the second conductive member forming the Peltier element or the Seebeck element; (4) a step of aligning the first region pattern, the second region pattern, and the third region pattern; (5) a step of filling, to the first region pattern, a solid, a liquid or a powder which is a material of the first conductive member and the second conductive member, to form the first region of the first conductive member and the second conductive member; (6) a step of filling, to the second region pattern, a solid, a liquid or a powder which is a material of the first conductive member and the second conductive member, to form the second region of the first conductive member and the second conductive member; (7) a step of filling, to the third region pattern, a solid, a liquid or a powder which is a material of the first conductive member and the second conductive member, to form the third region of the first conductive member and the second conductive member; (8) a step of integrally forming the both end parts and the intermediate part of each of the first conductive member and the second conductive member by joining by heating the solids, the liquids or the powders which are the material of the first conductive member and the second conductive member, and which is filled in the first region pattern, the second region pattern and the third region pattern; and (9) a step of joining one end portion of the first conductive member filled in the first region pattern, and one end portion of the second conductive member filled in the first region pattern, through a conductive joining member by an ohmic contact.

Moreover, according to still another aspect of the present invention, the manufacturing process for the Peltier element or the Seebeck element as claimed in claim 5, for manufacturing a plurality of Peltier elements or Seebeck elements, the manufacturing process further comprises: (9) a step of forming a plurality of regions of the one of the both end parts of the first conductive member simultaneously by using a plurality of the first region patterns; (10) a step of forming a plurality of regions of the one of the both end parts of the second conductive member simultaneously by using a plurality of the first region patterns; (11) a step of forming a plurality of regions of the intermediate part of the first conductive member simultaneously by using a plurality of the second region patterns; (12) a step of forming a plurality of regions of the intermediate part of the second conductive member simultaneously by using a plurality of the second region patterns; (13) a step of forming a plurality of regions of the other of the both end parts of the first conductive member simultaneously by using a plurality of the third region patterns; (14) a step of forming a plurality of regions of the other of the both end parts of the second conductive member simultaneously by using a plurality of the third region patterns; (15) a step of joining, by the ohmic contact, the region formed by the first region pattern and the region formed by the second region pattern of each of the first conductive member and the second conductive member; and (16) a step of joining, by the ohmic contact, the region formed by the second region pattern and the region formed by the third region pattern of each of the first conductive member and the second conductive member, so that a plurality of the peltier elements or the Seebeck elements are formed simultaneously.

### BRIEF DESCRIPTION OF DRAWINGS

FIG. 1 is a diagrammatic view showing a pai type Peltier/Seebeck element according to a first embodiment of the present invention.

FIG. 2 is a diagrammatic view showing a pai type Peltier/Seebeck element according to a second embodiment of the present invention.

FIG. 3 is a diagrammatic view showing a pai type Peltier/Seebeck element according to a third embodiment of the present invention.

FIG. 4 is a view showing a characteristic of an electric resistivity of a compound semiconductor forming an intermediate part of a first or second conductive member used in the pai type Peltier/Seebeck element according to the present invention.

FIG. 5 is a view showing a characteristic of a Seebeck coefficient of the compound semiconductor forming the intermediate part of the first or second conductive member used in the pai type Peltier/Seebeck element according to the present invention.

FIG. 6 is a view showing a characteristic of a thermal conductivity of the compound semiconductor forming the intermediate part of the first or second conductive member used in the Peltier/Seebeck element according to the present invention.

FIG. 7 is an experimental schematic diagram to confirm, by experiment, the Peltier effect and the Seebeck effect of the highly-functional type according to the embodiment of the present invention and the conventional type.

FIG. 8 is a view showing experimental results of the Peltier effect confirmed by the experiment of FIG. 7.

FIG. 9 is a view showing experimental results of the Seebeck effect confirmed by the experiment of FIG. 7.

FIG. 10 is a diagrammatic view to perform a simulation of a conventional type (with no constriction).

FIG. 11 is a diagrammatic view showing a copper plate used in the simulation.

FIG. 12 is a diagrammatic view showing a semiconductor used in the simulation.

FIG. 13 is a diagrammatic view to perform a simulation of the highly-functional type (with constriction) according to the embodiments of the present invention.

FIG. 14 is a diagrammatic view showing a semiconductor of a constriction portion used in the simulation.

FIG. 15 is a diagrammatic view deformed into cylindrical one dimension model for performing the simulation of the conventional type (with no constriction).

FIG. 16 is a schematic diagram for illustrating a radius of each portion of FIG. 15.

FIG. 17 is a diagrammatic view deformed into cylindrical one dimension model for performing the simulation of the highly-functional type (with constriction) according to the embodiment of the present invention.

FIG. 18 is a graph showing a simulation result of the conventional type (with no constriction) and the highly-functional type (with constriction) according to the embodiment of the present invention.

FIG. 19 is a graph showing a simulation result of the conventional type (with no constriction) and the highly-functional type (with constriction) according to the embodiment of the present invention.

FIG. 20 is a graph showing a simulation result of the conventional type (with no constriction) and the highly-functional type (with constriction) according to the embodiment of the present invention.

FIG. 21 is a graph showing a simulation result of the conventional type (with no constriction) and the highly-functional type (with constriction) according to the embodiments of the present invention.

FIG. 22 is a graph showing a simulation result of the conventional type (with no constriction) when the heating temperature is varied.

FIG. 23 is a graph showing a simulation result of the conventional type (with no constriction) when the heating temperature is varied.

FIG. 24 is a graph showing a simulation result of the conventional type (with no constriction) when the heating temperature is varied.

FIG. 25 is a graph showing a simulation result of the conventional type (with no constriction) when the heating temperature is varied.

FIG. 26 is a graph showing a simulation result of the conventional type (with no constriction) when the heating temperature is varied.

FIG. 27 is a graph showing a simulation result of the conventional type (with no constriction) when the heating temperature is varied.

FIG. 28 is a graph showing a simulation result of the conventional type (with no constriction) when the heating temperature is varied.

FIG. 29 is a graph showing a simulation result of the conventional type (with no constriction) when the heating temperature is varied.

FIG. 30 is a graph showing a simulation result of the highly-functional type (with constriction) according to one embodiment of the present invention when the heating temperature is varied.

FIG. 31 is a graph showing a simulation result of the highly-functional type (with constriction) according to one embodiment of the present invention when the heating temperature is varied.

FIG. 32 is a graph showing a simulation result of the highly-functional type (with constriction) according to one embodiment of the present invention when the heating temperature is varied.

FIG. 33 is a graph showing a simulation result of the highly-functional type (with constriction) according to one embodiment of the present invention when the heating temperature is varied.

FIG. 34 is a graph showing a simulation result of the highly-functional type (with constriction) according to one embodiment of the present invention when the heating temperature is varied.

FIG. 35 is a graph showing a simulation result of the highly-functional type (with constriction) according to one embodiment of the present invention when the heating temperature is varied.

FIG. 36 is a graph showing a simulation result of the highly-functional type (with constriction) according to one embodiment of the present invention when the heating temperature is varied.

FIG. 37 is a graph showing a simulation result of the highly-functional type (with constriction) according to one embodiment of the present invention when the heating temperature is varied.

FIG. 38 is a sectional side view showing a cast (one part of both end parts) for manufacturing first and second conductive members forming pai type Peltier/Seebeck element of the highly-functional type (with constriction) according to one embodiment of the present invention.

FIG. 39 is a plan view showing the cast (the one part of the both end parts) for manufacturing the first and second conductive members forming the pai type Peltier/Seebeck element of the highly-functional type (with constriction) according to one embodiment of the present invention.

FIG. 40 is a sectional side view showing the cast (an intermediate part) for manufacturing the first and second conductive members forming the pai type Peltier/Seebeck element of the highly-functional type (with constriction) according to one embodiment of the present invention.

FIG. 41 is a plan view showing the cast (the intermediate part) for manufacturing the first and second conductive members forming the pai type Peltier/Seebeck element of the highly-functional type (with constriction) according to one embodiment of the present invention.

FIG. 42 is a sectional side view showing the cast (the other part of the both end parts) for manufacturing the first and second conductive members forming the pai type Peltier/Seebeck element of the highly-functional type (with constriction) according to one embodiment of the present invention.

FIG. 43 is a plan view showing the cast (the other part of the both end parts) for manufacturing the first and second conductive members forming the pai type Peltier/Seebeck element of the highly-functional type (with constriction) according to one embodiment of the present invention.

FIG. 44 is a view showing a Peltier/Seebeck element of earlier technology.

### BEST MODE(S) FOR CARRYING OUT THE INVENTION

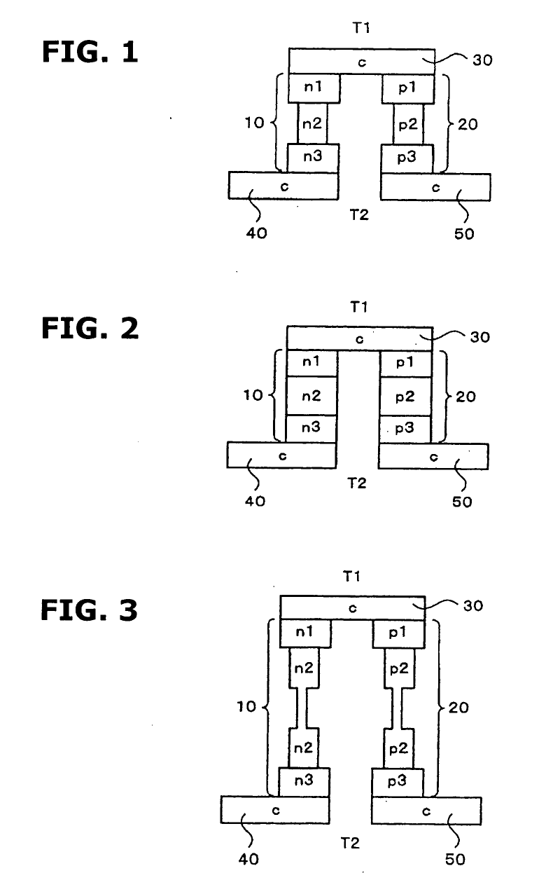

Hereinafter, a structure of a Peltier element or a Seebeck element according to the present invention and its manufacturing method will be illustrated with reference to the drawings. FIG. 1 is a diagrammatic view showing a structure of a Peltier element or a Seebeck element according to a first embodiment of the present invention.

As shown in FIG. 1, a first conductive member (a n-type semiconductor and so on) 10 having a predetermined Seebeck coefficient is composed of both end parts n1 and n3 thereof, and an intermediate part n2. Moreover, a second conductive member (a p-type semiconductor and so on) 20 having a Seebeck coefficient different from the Seebeck coefficient of the first conductive member is composed of both end parts p1 and p3 thereof, and an intermediate part p2.

The intermediate parts n2 and p2 of the first conductive member 10 and the second conductive member 20 have cross sections which are smaller than cross sections of the both end parts n1, n3, p1 and p3. Accordingly, the thermal conductivities of the intermediate parts become small relative to thermal conductivities of the both end parts, even when the same material is used.

One part n1 of the both end parts of this first conductive member 10 is joined to a joining member 30 by ohmic contact, and one part p1 of the both end parts of the second conductive member 20 is joined to a joining member 30 by the ohmic contact. This joining member 30 is heated to a temperature T1, and constitutes a high temperature part. Moreover, the other part n3 of the both end parts of the first conductive member 10 is joined to a joining member 40 by the ohmic contact, and the other part p3 of the both end parts of the second conductive member 20 is joined to a joining member 50 by the ohmic contact. These joining member 40 and the joining member 50 are set to a temperature T2, and constitute low temperature part. That is, it is T1>T2.

In the element with the above-described structure, in a case in which the joining member 30 is held to the high temperature (T1) and circumferences of the joining member 40 and 50 are held to the low temperature (for example, room temperature T2), there is a generated a thermal electromotive force proportional to a temperature difference between the joining members 30, 40 and 50. This is a Seebeck effect. In this case, the joining member 30 and the joining member 40 are connected by the first conductive member 10, and the joining member 30 and the joining member 50 are connected by the second conductive member 20. Accordingly, in the first conductive member 10 and the second conductive member 20, in a case of using a member structure (the first conductive member 101 and the second conductive member 102 in FIG. 44) with a thermal conductivities which are identical to the thermal conductivities of the conventional example (cf. FIG. 44), the movement of the heat from the high temperature portion (for example, the joining member 30 in FIG. 1) to the low temperature portion (for example, the joining members 40 and 50 in FIG. 1) become fast. Consequently, the temperatures of the both members and the circumferences of the joining members 40 and 50 become heat balance state at short times, and the temperature difference between the joining members 30, 40 and 50 becomes extremely small, so that the electromotive force is not generated. However, in the example according to the first embodiment of the present invention shown in FIG. 1, the intermediate parts n2 and p2 of the first conductive member and the second conductive member have, respectively, the cross sections which are smaller than the cross sections of the both end parts n1, n3 and p1, p3 thereof, so as to deteriorate the thermal conductivities. Hence, it is possible to hold the temperature difference between the joining members 30, 40 and 50 to the large value, and thereby to bring out the Seebeck effect. Therefore, a conversion efficiency from the thermal energy to the electric energy, that is the thermoelectric conversion efficiency is improved.

Next, in the element with the structure shown in FIG. 1, when the joining members 40 and 50 are electrically connected to apply the electric current, the heat generation and the heat absorption which are proportional to the amount of the electric current are caused between the joining member 30 and the joining members 40 and 50. This effect is the Peltier effect. An element causing the this effect is a Peltier element. These heat absorption and heat generation are caused on the opposite surfaces of the first conductive member 10 and the second conductive member 20 in accordance with directions of the electric current. That is, if the joining member 30 is the heat generation side in one direction of the electric current, the joining members 40 and 50 become the heat generation side in the opposite direction of the electric current. In this state, there is caused electrical thermal transfer from the absorption side, for example, the joining members 40 and 50's side, through the first conductive member 10 and the second conductive member 20, to the joining member 30's side of the heat generation side. Consequently, the temperature difference is generated between the joining member 30 and the joining members 40 and 50. In this case, in the embodiment of the present invention, the intermediate parts n2 and p2 of the first conductive member 10 and the second conductive member 20 have cross sections which are smaller than the cross sections of the both end parts n1, n3, p1 and p3, and accordingly the thermal conductive coefficients become small. Therefore, the movements of the heat quantities become small for the small thermal conductive coefficients, and it is possible to keep the temperature difference between the heat side and the heat generation side, to the large quantity. The electrical thermal transfer to the heat generation side is effectively performed by absorbing the more thermal energy from the circumference on the heat absorption side.

In this way, the heat absorption effect and the heat generation effect by the Peltier effect continue while the electric current is applied, and accordingly the temperature difference between the joining member 30 and the joining members 40 and 50 is increased as the movement of the heat quantities between the joining member 30 and the joining members 40 and 50 become slower. Therefore, it is possible to enhance function of the Peltier element used in order to maximize the temperature difference between the joining member 30 and the joining members 40 and 50, to follow that intent.

In this way, in FIG. 1, the intermediate parts of the first conductive member 10 and the second conductive member 20 have the cross sections which are smaller than the cross sections of the both end parts thereof, so that the thermal conductivities become small. In a second embodiment of the present invention, for example, as shown in FIG. 2, the first conductive member 10 and the second conductive member 20 have the same cross sectional shape. It is optional to use, as material of the intermediate parts n2 and p2, for example, material with a thermal conductivity which is smaller than a thermal conductivity of both end parts n1, p1 or n3, p3, such as amorphous silicon and polysilicon.

Moreover, in a third embodiment of the present invention, as shown in FIG. 3, the intermediate parts n2 and p2 of the first conductive member 10 and the second conductive member 20 are further divided to form constrictions (for example, to form narrow width portions in the intermediate parts of the first conductive member 10 and the second conductive member 20). That is, it is optional to form shapes with small cross sections by dividing the intermediate parts n2 and p2 itself into a plurality of parts. Thereby, it is possible to further decrease the thermal conductivities of the intermediate parts n2 and p2, and to decrease the semiconductor material. Consequently, it is possible to further increase the temperature difference between the high temperature side and the low temperature side.

In the Peltier/Seebeck elements according to the embodiments of the present invention as shown in FIGS. 1˜3, for providing function to enhance the Peltier effect or the Seebeck effect, the first conductive member n1, n2 and n3 and the second conductive member p1, p2 and p3 may have the same Seebeck coefficient respectively, and a part or all of n1, n2, n3 and p1, p2, p3 may have different Seebeck coefficients.

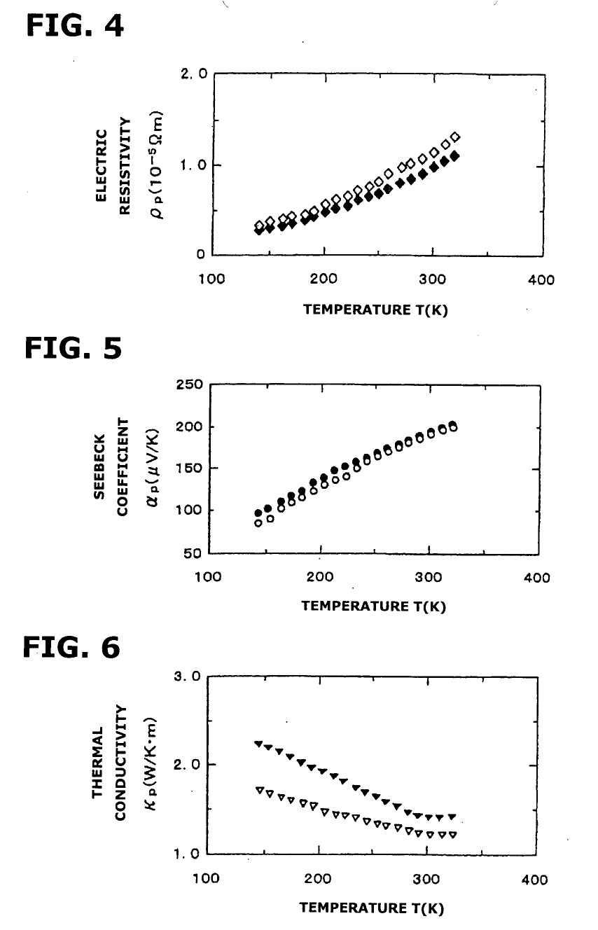

Moreover, for providing function to enhance the Peltier effect or the Seebeck effect, the intermediate parts n2 and p2 of the first conductive member n1, n2 and n3 and the second conductive member p1, p2 and p3 are formed from compound semiconductor such as Bi_{0.5}Sb_{1.5}Te₃ of p-type which has property characteristic shown in FIGS. 4˜6 (symbols (♦), (◯), (▾) in FIGS. 4˜6 are dissolution material, and symbols (⋄), (), (∇) are sintered body). That is, FIG. 4 shows that the electric resistivity is increased with respect to the temperature (T). FIG. 5 shows that the Seebeck coefficient is increased with the increase of the temperature (T). Moreover, FIG. 6 shows that the thermal conductivity coefficient is decreased with the increase of the temperature (T). In this way, in the property value of the compound semiconductor, the Seebeck coefficient is increased, the thermal conduction coefficient is decreased with the increase of the temperature. The compound semiconductor having this property is being further developed.

In this way, the semiconductor (the semiconductor made from the material different from the material of parts other than the intermediate part) whose the material is varied is interposed in the intermediate part of the first or second conductive member, and accordingly the thermal conductivity of the material of the intermediate part is decreased with the increase of the temperature when the heat of the high temperature side is transmitted through the intermediate part to the low temperature side. Consequently, the heat of the high temperature side becomes difficult to transmit through the intermediate part to the low temperature side. Therefore, it is possible to keep the temperature difference between the high temperature side and the low temperature side to the larger amount.

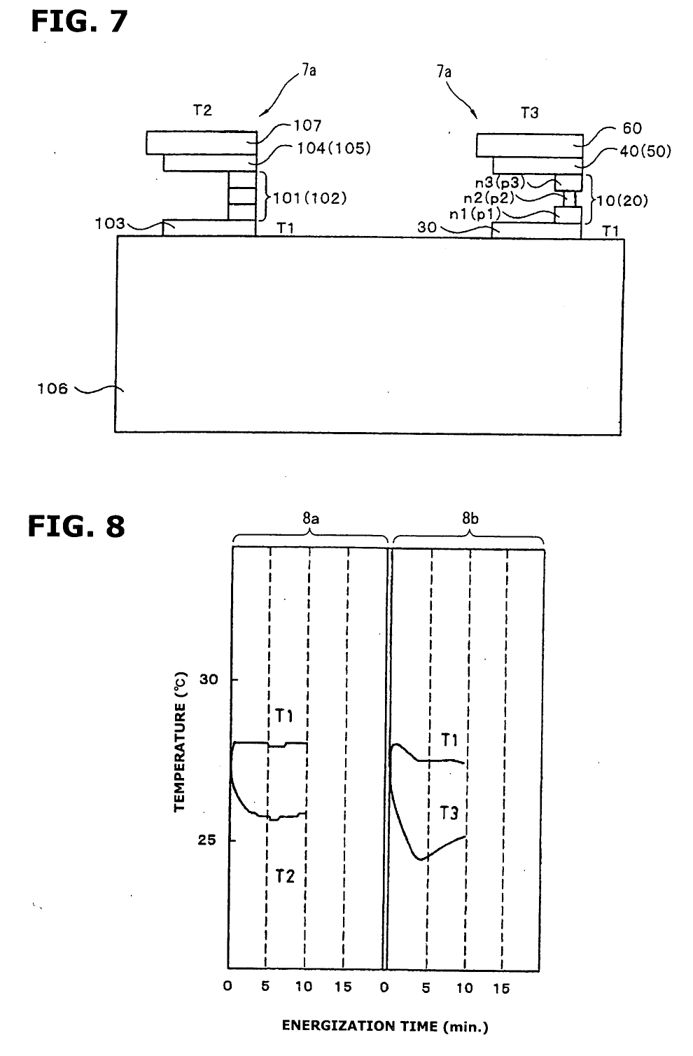

Next, with reference to FIG. 7, an example of experiment about the Peltier/Seebeck element according to the embodiment of the present invention will be illustrated. In this experimental example, an experiment using the conventional Peltier/Seebeck element and an experiment using the Peltier/Seebeck element according to the embodiment of the present invention are performed to form comparison data.

A symbol 7a of FIG. 7 shows a conventional Peltier/Seebeck element of FIG. 44. The first conductive member 101 or the second conductive member 102 is joined to the joining member 103 or the joining member 104 (105) of the copper plate and so on. The joining member 103 is connected with a heat sink 106. Besides, a symbol 107 in FIG. 7 designates a reinforcement member arranged to reinforce strength of the joining member 104 (105), and is made of the cooper plate.

Moreover, a symbol 7b of FIG. 7 shows the Peltier/Seebeck element as shown in FIG. 1, according to the embodiment of the present invention. One end of the first conductive member 10 or the second conductive member 20 which is a component of the Peltier/Seebeck element is joined through the joining member 30 to the heat sink 106. Besides, a symbol 60 in FIG. 7 designates a reinforcement member arranged to reinforce strength of the joining member 40 (50), like the symbol 107 in FIG. 7, and is made of the cooper plate. As shown in FIG. 1, the first conductive member 20 and the second conductive member 30 have shapes or materials so that the intermediate part n2 (p2) has the thermal conductivity lower than the thermal conductivities of the both end parts n1 (p1) and n3 (p3). In this first embodiment, the cross section of the intermediate part is smaller than the cross section of the both end parts, so that the thermal conductivity of the intermediate part is decreased. The Seebeck coefficient or the Peltier coefficient of this n-type semiconductor n1, n2 and n3 (or p-type semiconductor p1, p2 and p3) may be identical to each other, or may be set to appropriate values by combining the materials with the different Seebeck coefficients or Peltier coefficients.

FIG. 8 is a graph plotting the temperature characteristic when the electric current is applied to both of the conventional Peltier/Seebeck element and the highly-functional Peltier/Seebeck element according to the embodiment of the present invention as shown in FIG. 7. A horizontal axis represents a time after the electric current is applied. A vertical axis represents a temperature of the joining member. A scale of the horizontal axis represents 5 minutes. A symbol 8a of FIG. 8 shows a graph plotting temperatures of the joining members 103 and 104 (105) in the Peltier/Seebeck element of the conventional type (corresponding to a symbol 7a of FIG. 7) when the electric current of, for example, 1 ampere (A) is applied between the joining members 103 and 104 (105). As understood from this drawing, the temperatures of the joining members located on the both sides of the conductive member are the same value at initiation of the energization. As the energization time elapses, the temperature T1 of the joining member 103 on a side that the heat sink 106 exists varies hardly. However, the temperature of the joining member 104 (105) on a side that the heat sink 106 does not exist is gradually decreased, and shifted to temperature rise from after 5 minutes. This shows that the conversion from the temperature decrease to the temperature increase is caused since the temperature decrease by the heat absorption of the Peltier effect is inhibited by the movement of the thermal energy from the high temperature side to the low temperature side by the heat conduction in the semiconductor 101 (102).

Next, a symbol 8b of FIG. 8 shows a result in the embodiment of the present invention, that the same experiment as the conventional Peltier/Seebeck element is performed. This experiment result shows a measurement of the temperatures of the joining member 30 and the joining member 40 (50) when the electric current of the substantially 1 ampere (A) is applied between the joining member 30 and the joining member 40 (50) of the symbol 7b of FIG. 7.

As understood from the symbol 8b of FIG. 8, the temperature of the joining member 30 on a side that the heat sink 106 is joined remains at substantially constant T1. However, the temperature of the joining member 40 (50) on a side that the heat sink 106 is not joined is rapidly decreased as the time elapses.

As understood from the symbol 8b of this FIG. 8, in the highly-functional Peltier/Seebeck element according to the embodiment of the present invention, the temperature difference between the joining member 30 and the joining member 40 (50) is further increased as the time elapses, relative to the conventional type (cf. the symbol 8a of FIG. 8). This shows that, in the highly-functional Peltier/Seebeck element used in the embodiment of the present invention, the thermal conductivity of the semiconductor part 10 (20) is set to the small value to inhibit the movement of the thermal energy from the high temperature side to the low temperature side by the thermal conductivity, the supply of the heat energy to the low temperature side is decreased, and the temperature of the low temperature side is further decreased by the absorption by the Peltier effect.

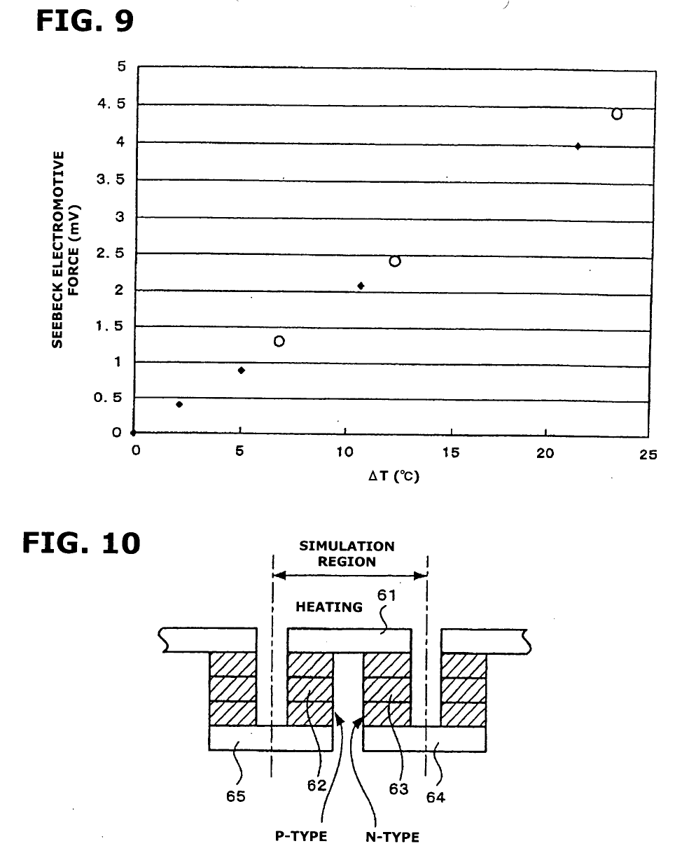

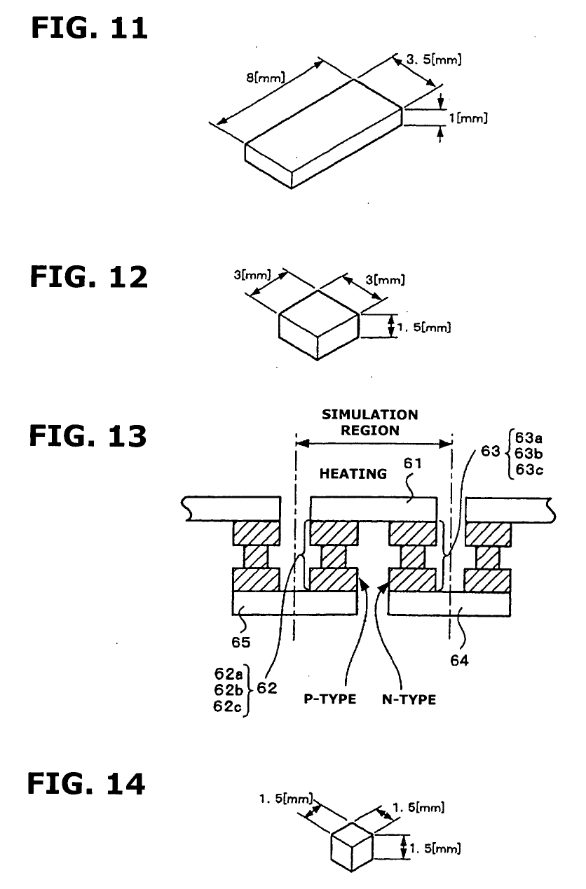

Next, with reference to FIG. 9, the Seebeck effect is verified in the conventional Peltier/Seebeck element and the highly-functional Peltier/Seebeck element used in the embodiment of the present embodiment. In FIG. 9, a horizontal axis represents a temperature difference between the two joining members, and a vertical axis represents a Seebeck electromotive force. In FIG. 9, (◯) represents an electromotive force of the highly-functional Peltier/Seebeck element used in the embodiment of the present invention, and (♦) represents the electromotive force generated by the conventional Peltier/Seebeck element. As is clear from this FIG. 9, both of the conventional type and the highly-functional element according to the present invention output the Seebeck electromotive forces which are proportional to the temperature difference, and which are aligned in the same straight line, and it is understood that the highly-functional element according to the present invention does not affect the Seebeck effect. At the same time, in the highly-functional Peltier/Seebeck element Seebeck according to the present invention that the thermal conductivity of the semiconductor part is decreased, the temperature difference between the high temperature side and the low temperature side is held to the large value, and accordingly this experiment verifies that the output of the Seebeck electromotive force can be greater than that of the conventional type.

FIGS. 10˜14 show an example of an actual structure of the highly-functional Peltier/Seebeck element (the constriction is provided to the first or second conductive member) according to the embodiment of the present invention, and an example of an actual structure of the conventional type Peltier/Seebeck element (the constriction is not provided to the first or second conductive member). FIGS. 10˜12 show the conventional Peltier/Seebeck element, and FIGS. 13 and 14 show the example in case of connecting the highly-functional Peltier/Seebeck element according to the embodiment of the present invention. The copper plate serving as the joining member uses a rectangular parallelepiped shape of 8 mm length, 3.5 mm width, and 1 mm height. The simulation experiment is performed by assuming a member formed by stacking, in three-tiered, a rectangular parallelepiped of 3 mm length and width, and 1.5 mm height, as the semiconductor constituting the first conductive member and the second conductive member. Besides, the same simulation experiment is performed by assuming a cube of 1.5 mm length and width, and 1.5 mm height, as the material of the intermediate parts of the first and second conductive members constituting the highly-functional Peltier/Seebeck element used in the embodiment of the present invention. Moreover, to re-create an actual circuit experiment, the simulation experiment is performed by using a boundary condition that the room temperature is set to constant temperature, and a preset temperature of the copper plate of the joining member on the heat side is varied, and the temperature of the copper plate of the joining member on the opposite side opposed to the heat side is automatically determined without physical discrepancy by the heat conduction in the circuit and the heat transfer to the air (the air that has the same temperature as the room temperature around the circuit). Besides, the speed of the movement of the heat quantity by the heat conduction in the circuit is extremely greater than the speed of the movement of the heat quantity by the heat transfer to the air having the same temperature as the room temperature, and it is verified that the actual circuit experimental data can be quantitatively re-created by repeating preliminary simulations to examine whether the actual circuit experiment can be re-created by the one-dimensional cylindrical model.

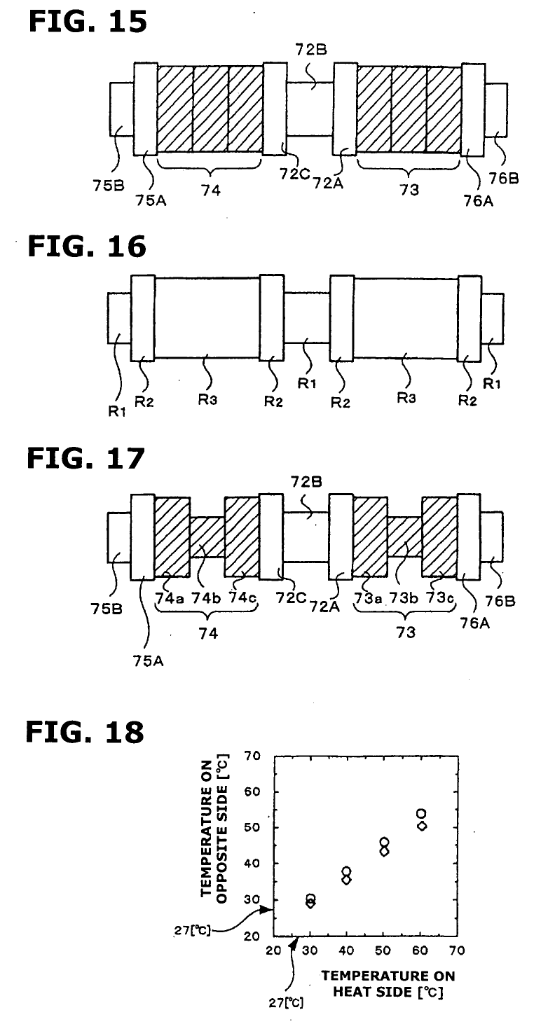

FIGS. 15˜17 are views showing a one-dimensional cylindrical model of 1 cycle of the circuit shown in FIGS. 10˜14. The simulation experiment is performed by this model.

In the cylindrical simulation model of the conventional Peltier/Seebeck element shown in FIGS. 15 and 16 (R; a radius of the member of the cylindrical model), a first conductive member 73 (n-type semiconductor) and a second conductive member 74 (p-type semiconductor) are formed by stacking, in the three-tiered, cylindrical members having a radius of R3 (=1.693 mm), a 1.5 mm height (a distance in right and left directions in FIGS. 15˜17), and stacked in three-tiered. The first conductive member 73 is joined to a cylindrical joining member 72A of a radius R2 (=1.829 mm), and 1 mm height. This joining member 72A is joined to a cylindrical member 72B of a radius R1 (=1.056 mm), and 2 mm height. Moreover, the cylindrical joining member 72B is joined to a joining member 72C. The joining member 72C has the same shape as the joining member 72A. These joining members 72A˜72C are forcibly heated from the outside in the simulation experiment. Moreover, the second conductive member 74 is formed of the p-type semiconductor which is different in the Seebeck coefficient to the first conductive member 73. However, the second conductive member 74 has the same shape as the first conductive member 73.

The other end of the first conductive member 73 is joined to the joining member 76a which has the same shape as the joining member 72A. The joining member 76A is joined to the joining member 76B which has the same shape as the joining member 72B. Moreover, the other end of the second conductive member 74 is joined to the joining member 75A which has the same shape as the joining member 72C. This joining member 75A is joined to the joining member 75B which has the same shape as the joining member 72B (the joining member 76A is joined to the 76B which has the same shape as the joining member 72B).

On the other hand, the highly-functional Peltier/Seebeck element as shown in FIG. 17, according to the embodiment of the present invention is identical in structure to the conventional Peltier/Seebeck element of FIGS. 15 and 16, except for the structures of the first conductive member 73 and the second conductive member 74. That is, the first conductive member 73 in FIG. 17 is composed of both end parts 73a and 73c, and an intermediate part 73b. A radius R4 (=0.85 mm) of the intermediate part 73b is substantially half of the radius R3 (=1.693 mm) of the both end parts.

FIGS. 18˜21 show simulation results of the simulation experiments performed, at the constant room temperature 27° C., by using the above-described structure of the conventional Peltier/Seebeck element (with no constriction) and the above-described structure of the highly-functional Peltier Seebeck element (with the constriction) according to the embodiment of the present invention (in FIGS. 18˜21, a symbol (◯) designates the no constriction, and a symbol (⋄) designates the constriction).

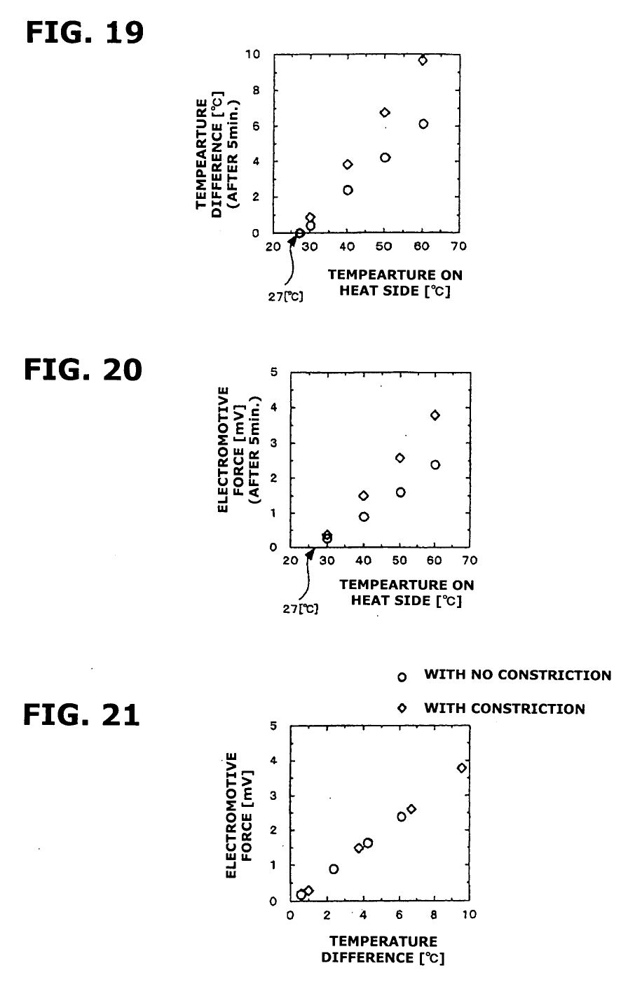

FIG. 18 is a graph showing variation of the temperature of the opposite side (the joining members 75A, 75B, 76A and 76B in FIGS. 15˜17) opposite to the heat side, relative to the temperature of the heat side, after 5 minutes of heating that the temperature of each point in the circuit becomes static state from time when the heat side (the joining members 72A˜72C in FIGS. 15˜17) is forcibly heated from the outside. In a case in which the temperature of the heat side is gradually increased from initiation temperature of 27° C., the temperature of the opposite side is gradually increased after the 5 minutes of heating, becoming the static state. As understood from this FIG. 18, in case of the conventional type (with no constriction), the temperature increase of the opposite side is increased with the temperature increase of the heat side, relative to the highly-functional type (with the constriction). FIG. 19 shows a relationship between a temperature difference between the heat side and the opposite side after the 5 minutes of heating, becoming the static state, and the temperature of the heat side. As understood from FIG. 19, the temperature difference of the both in the highly-functional type (with the constriction) is greater than the temperature difference of the both in the conventional type (with no constriction). That is, in the highly-functional type (with the constriction), the heat is difficult to transmit in the first or second conductive member, and accordingly it is possible to attain the temperature difference larger than the temperature difference in the conventional type (with no constriction).

FIG. 20 shows a graph plotting the electromotive force after the 5 minutes of heating, becoming the static state. From this drawing, when the temperature on the heat side is set to, for example, 60° C., in the highly-functional type (with the constriction), it is possible to attain large electromotive force substantially 1.6 times greater than that of the conventional type (with no constriction). FIG. 21 shows a graph plotting the electromotive force with respect to the temperature difference between the heat side and the non-heat side (the opposite side). In the conventional type (with no constriction) and also the highly-functional type (with the constriction), simulation date are aligned in the same straight line. This means that the obtained electromotive force is proportional to the temperature difference. Accordingly, it was verified that the highly-functional type (with the constriction) which attains the temperature difference larger than the temperature difference in the conventional type has a function capable of generating the higher Seebeck effect electromotive force.

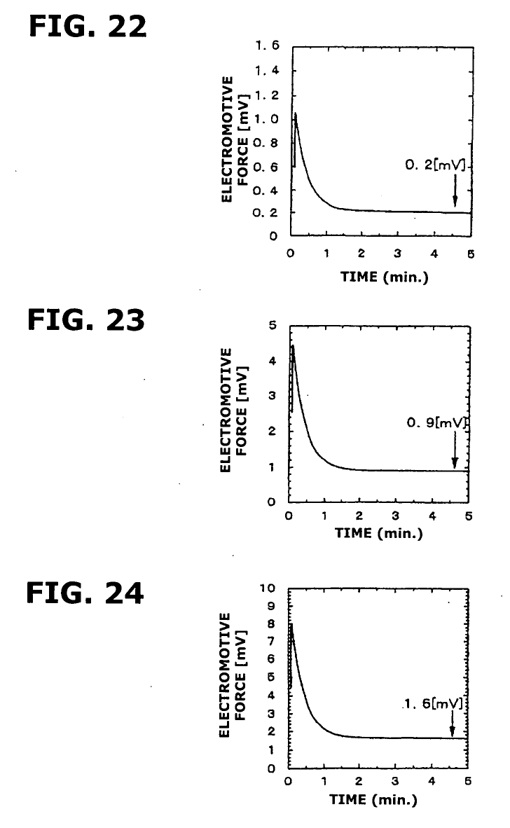

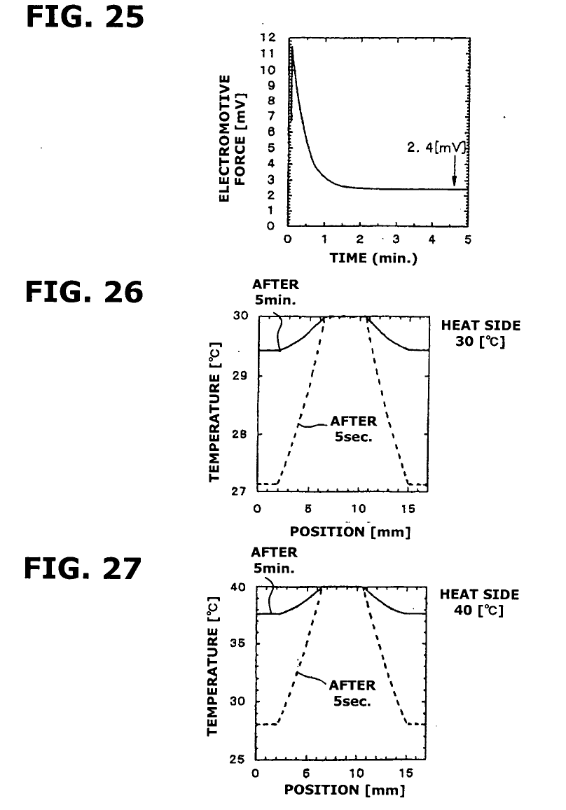

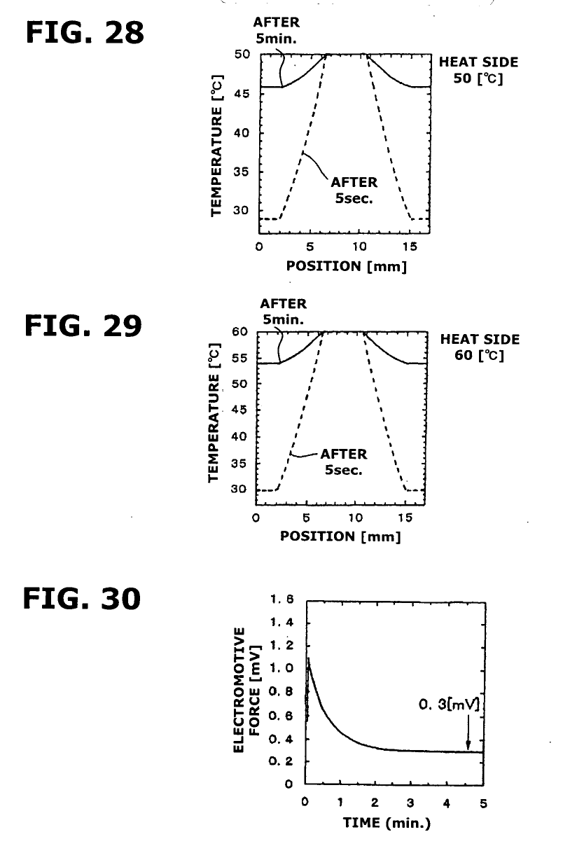

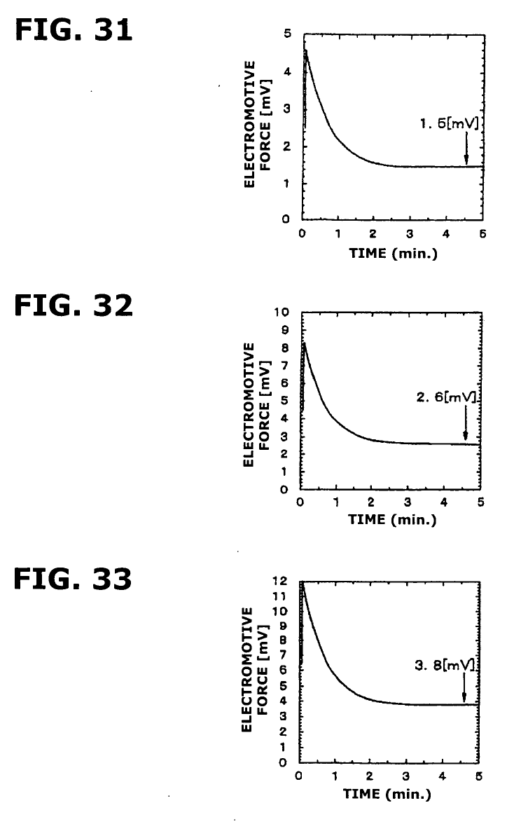

FIGS. 22˜29 show, by using the temperature on the heat side as parameter, relationship between the elapsed time period from the heating and the electromotive, and relationship between position and the temperature of the first or second conductive member, in the Peltier/Seebeck element of the conventional type (with no constriction).

FIGS. 22˜25 show simulation results of the electromotive force with respect to the time period of the heating, at four heating temperatures of 30° C., 40° C., 50° C. and 60° C. At the heating temperature of 30° C., 40° C., 50° C. and 60° C., the electromotive forces become 0.2 mV, 0.9 mV, 1.6 mV and 2.4 mV, respectively, after the 5 minutes of heating, becoming the static state. Moreover, FIGS. 26˜29 show graph plotting, by using the heating temperature as parameter, the temperatures of positions in a case in which a position of a left end of the member 75B in FIG. 15 is 0 mm, and a position of a right end of the member 76B in FIG. 15 is 17 mm. Dotted lines in the drawings represent the temperature in 5 seconds of the heating time. Solid lines represent the temperature after the 5 minutes of heating, becoming the static state. As is clear from these drawings, it is understood that the temperature difference between the heat side (portions near center in the drawings) and the opposite side (both end portions in the drawings) surrounded by the air at the room temperature becomes small as the heating time elapses.

FIGS. 30˜37 show relationship between elapsed time period from the heating and the electromotive force, and relationship between position and the temperature of the first or second conductive member, when the same simulation as FIGS. 22˜29 is performed by using the temperature of the heat side as parameter in the Peltier/Seebeck element according to the embodiment of the present invention.

FIGS. 30˜33 show simulation results of the electromotive force with respect to the time from the heating, at four heating temperatures of 30° C., 40° C., 50° C. and 60° C. As understood from FIGS. 30˜33, at the heating temperatures 30° C., 40° C., 50° C. and 60° C., the electromotive force are 0.3 mV, 1.5 mV, 2.6 mV and 3.8 mV, respectively, after the 5 minutes of heating, becoming the static state. It is understood that these become 1.6 times greater than those of FIGS. 22˜25.

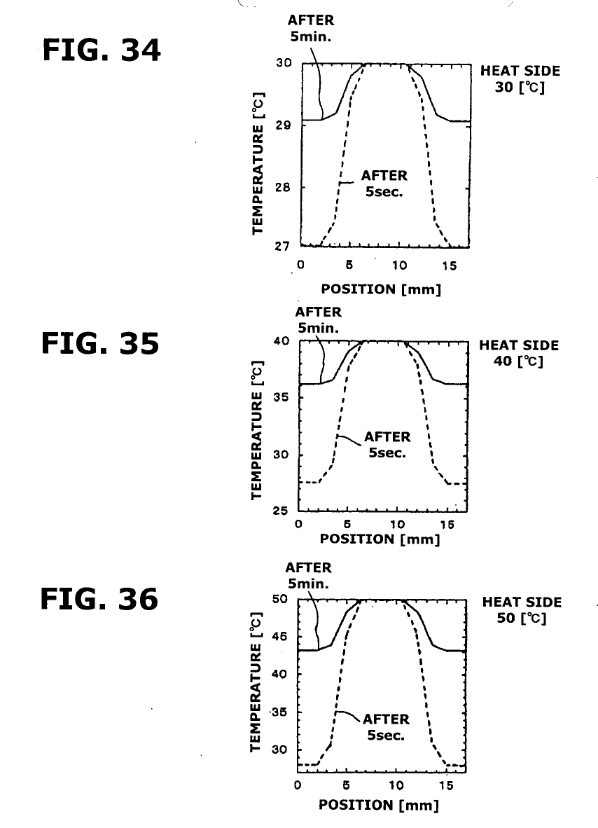

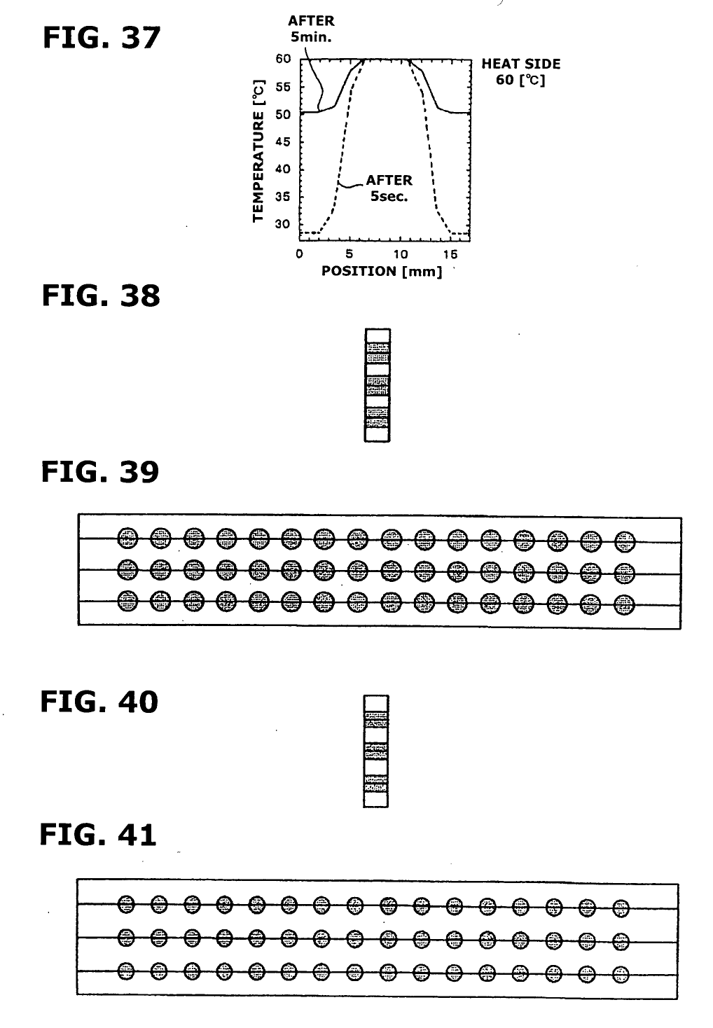

Moreover, FIGS. 34˜37 show graphs plotting, by using the heating temperature as parameter, temperatures of positions in a case in which a position of a left end of the member 75B in FIG. 17 is 0 mm, and a right end of the member 76B in FIG. 17 is 17 mm. Dotted lines show temperatures in the 5 seconds of the heating time, and solid lines show temperatures after the 5 minutes of heating, becoming the static state. As is clear from these drawings, the temperature difference between the heating part and the both end portions becomes small by the thermal conduction in the circuit as the time elapses. However, it is understood that the static state is achieved in a state that the temperature difference is large relative to the conventional type (with no constriction), and that this large temperature difference is achieved in a region of the constriction of the semiconductor.

In this way, the simulation results of the conventional type (with no constriction) as shown in FIGS. 22˜29 and the simulation results of the highly-functional type (with the constriction) as shown in FIGS. 30˜37 show that the electromotive force is clearly larger in the highly-functional type (with the constriction), and that the temperature difference between the heated part and the opposite side part surrounded by the room temperature air becomes large after the 5 minutes of heating, becoming the static state, in the highly-functional type (with the constriction). This is because the Peltier/Seebeck element of the highly-functional type (with the constriction) becomes smaller than the conventional type (with no constriction), in the thermal conductivity from the heating part to the opposite side part surrounded by the room temperature air. By these simulation results, it is verified that the Seebeck effect and the Peltier effect become large in Peltier/Seebeck element of the highly-functional type (with the constriction) according to the embodiment of the present invention.

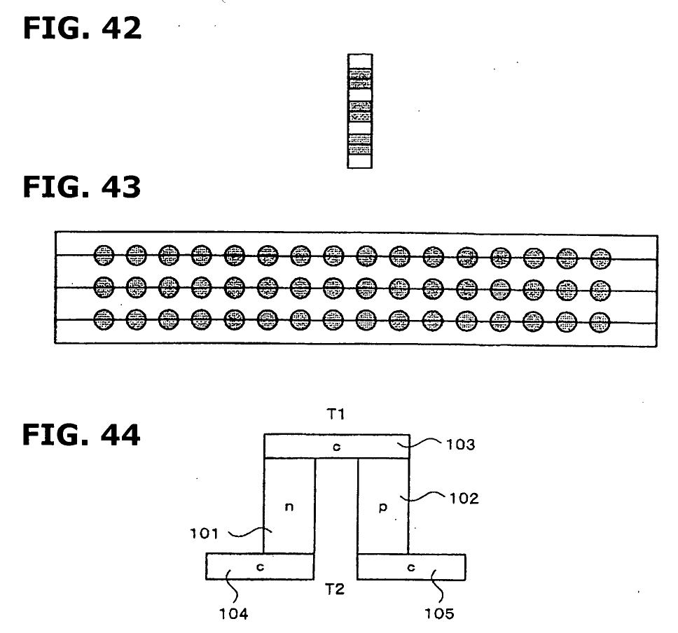

Next, with reference to FIGS. 38˜43, manufacturing method of the Peltier/Seebeck element of the highly-functional type (with the constriction) according to the embodiment of the present invention will be illustrated. FIG. 38 (a plan view) and FIG. 39 (a side view) show a cast for manufacturing forty eight of the first conductive member 10 or the second conductive member 20 simultaneously. FIGS. 38 and 39 show a cast for manufacturing one of the both end parts when the first conductive member 10 or the second conductive member 20 is divided into three parts. Similarly, FIG. 40 (a front view) and FIG. 41 (a side view) show a cast for the intermediate part (n2 or p2) of the first conductive member 10 or the second conductive member 20, and FIG. 42 (a front view) and FIG. 43 (a side view) show the other (n3 or p3) of the both end parts of the first conductive member 10 or the second conductive member 20. In these drawings, the first conductive member 10 or the second conductive member 20 has a cylindrical cross section. However, it is not necessary that the shape is the cylindrical shape, and the shape may be a rectangular or another polygon. In this case, it is important that the cross section of the intermediate part shown in FIGS. 40 and 41 is smaller than the cross sections of the both end parts shown in FIGS. 38, 39 and 42, 43.

FIGS. 38˜43 show the manufacturing method of the Peltier/Seebeck elements of the highly-functional type (with the constriction) according to the first embodiment of the present invention. In the second embodiment of the present invention, the cross sections of parts of the semiconductors of FIGS. 38˜43 are set identical to one another, and the material (the semiconductor material within the cast shown in FIGS. 40 and 41) of the intermediate part is varied to a material with the small thermal conductivity such as amorphous silicon or polysilicon. Accordingly, it is possible to manufacture the Peltier/Seebeck element manufacture the Peltier/Seebeck element which can attain the same Seebeck effect as the Peltier/Seebeck element of the highly-functional (with the constriction) according to the first embodiment of the present invention.

Besides, it is optional to apply various methods, and to apply, for example, a photo mask method, except for the method that uses the cast formed into a desired shape as shown in FIGS. 38˜43 for forming each pattern of the both end parts and the intermediate part of the first conductive member 10 or the second conductive member 20. Moreover, it is optional to apply, to each pattern, various materials (for example, material finally solidified by the heating and the pressurization and so on by inserting the material which has the small conductivity, and which is, for example, solid, liquid or powder) which is used in the Peltier/Seebeck element, except for the material with the small thermal conductivity such as the above-described amorphous silicon or the polysilicon.

As illustrated above, in the Peltier/Seebeck element of the conventional type (with no constriction), the semiconductor forming the first conductive member or the second conductive member has the relative large thermal conductivity of substantially one-two hundredth of the copper, and accordingly the temperature ΔT between the upper temperature T1 and the lower temperature T2 of the semiconductor becomes small in the static state. Consequently, there is a problem to enormously decrease the Peltier effect and the Seebeck effect. Contrarily, in the structure of the Peltier/Seebeck element of the highly-functional type (with the constriction) according to the embodiments of the present invention, the intermediate part of the first or second conductive member is formed into the shape to decrease the thermal conductivity, or employs the material with the small thermal conduction coefficient. Consequently, it is possible to keep the temperature difference ΔT between the upper temperature T1 and the lower temperature T2, to the large value even in the static state, relative to the Peltier/Seebeck element of the conventional type. Therefore, it is possible to largely exert the Peltier effect and the Seebeck effect along the intended purpose.

Accordingly, in the structure of the Peltier/Seebeck element of the highly-functional type (with the constriction) according to the embodiment of the present invention, the thermal conductivities of the intermediate parts of the first conductive member and the second conductive member forming the element is smaller than the thermal conductivities of the both end parts thereof. Accordingly, the heat conduction from the high temperature side to the low temperature side is deteriorated, and the movement of the thermal energy from the high temperature side to the low temperature side is decreased. Therefore, the use efficiency of the thermal energy is improved.

Moreover, a plurality of elements can be simultaneously formed on the substrate, and it is possible to ensure the uniformity of each element, and to decrease the manufacturing cost of the elements.

Although the embodiment of the present invention has been described above by reference to the figures, the invention is not limited to the embodiments described above. Various forms and modifications are included as long as they are not deviated from the gist of the invention.

The integrated parallel Peltier Seebeck element chip fabricating process according to the present invention can significantly reduce the time required for fabrication conventionally performed by a skilled technician or technicians, by applying the LSI fabricating technique to the integrated Peltier Seebeck element chip fabricating process.

Moreover, a multitude of integrated parallel Peltier Seebeck element chip are formed simultaneously, and multi terminal connectors are provided. Therefore, integrated Peltier Seebeck panels and sheets can be produced by a simple method by combining the integrated parallel Peltier Seebeck element chips. Consequently, it is possible to assemble an integrated system for direct conversion from thermal energy to electric energy and an integrated system for transfer of thermal energy, by incorporating the Peltier Seebeck panel or panels or sheet or sheets very quickly.

1. A structure of a Peltier element or a Seebeck element comprising (characterized in that):
a first conductive member and a second conductive member forming the Peltier element or the Seebeck element, having different Seebeck coefficients, and each including an intermediate part in a longitudinal direction which has a thermal conductivity smaller than thermal conductivities of both end parts.

2. The structure of the Peltier element or the Seebeck element as claimed in claim 1, wherein the intermediate parts of the first conductive member and the second conductive member in the longitudinal direction which are other than the both end parts have cross sections smaller than the cross sections of the both end parts.

3. The structure of the Peltier element or the Seebeck element as claimed in claim 1, wherein the intermediate parts of the first conductive member and the second conductive member in the longitudinal direction which are other than the both end parts is formed from a material which has a thermal conductivity smaller than a thermal conductivity of a material of the both end parts, and which has a Seebeck coefficient different from a Seebeck coefficient of the both end parts.

4. The structure of the Peltier element or the Seebeck element as claimed in claim 1, wherein the intermediate parts of the first conductive member and the second conductive member in the longitudinal direction which are other than the both end parts are divided into a plurality of parts to vary sectional shapes.

5. A manufacturing process for a Peltier element or a Seebeck element including a first conductive member and a second conductive member having different Seebeck coefficients, and each having an intermediate part in a longitudinal direction which has a thermal conductivity smaller than thermal conductivities of both end parts, the manufacturing process comprising:
a step of forming a first region pattern by forming a cast, and by forming a pretreatment pattern by using a photo mask method to form a first region which is a region of one of the both end parts of each of the first conductive member and the second conductive member forming the Peltier element or the Seebeck element;
a step of forming a second region pattern by forming a cast, and by forming a pretreatment pattern by using a photo mask method to form a second region which is a region of one of the intermediate part of each of the first conductive member and the second conductive member forming the Peltier element or the Seebeck element;
a step of forming a third region pattern by forming a cast, and by forming a pretreatment pattern by using a photo mask method to form a third region which is a region of the other of the both end parts of each of the first conductive member and the second conductive member forming the Peltier element or the Seebeck element;
a step of aligning the first region pattern, the second region pattern, and the third region pattern;
a step of filling, to the first region pattern, a solid, a liquid or a powder which is a material of the first conductive member and the second conductive member, to form the first region of the first conductive member and the second conductive member;
a step of filling, to the second region pattern, a solid, a liquid or a powder which is a material of the first conductive member and the second conductive member, to form the second region of the first conductive member and the second conductive member;
a step of filling, to the third region pattern, a solid, a liquid or a powder which is a material of the first conductive member and the second conductive member, to form the third region of the first conductive member and the second conductive member;
a step of integrally forming the both end parts and the intermediate part of each of the first conductive member and the second conductive member by joining by heating the solids, the liquids or the powders which are the material of the first conductive member and the second conductive member, and which is filled in the first region pattern, the second region pattern and the third region pattern; and
a step of joining one end portion of the first conductive member filled in the first region pattern, and one end portion of the second conductive member filled in the first region pattern, through a conductive joining member by an ohmic contact.

6. The manufacturing process for the Peltier element or the Seebeck element as claimed in claim 5, further comprising:
a step of forming a plurality of regions of the one of the both end parts of the first conductive member simultaneously by using a plurality of the first region patterns;
a step of forming a plurality of regions of the one of the both end parts of the second conductive member simultaneously by using a plurality of the first region patterns;
a step of forming a plurality of regions of the intermediate part of the first conductive member simultaneously by using a plurality of the second region patterns;
a step of forming a plurality of regions of the intermediate part of the second conductive member simultaneously by using a plurality of the second region patterns;
a step of forming a plurality of regions of the other of the both end parts of the first conductive member simultaneously by using a plurality of the third region patterns;
a step of forming a plurality of regions of the other of the both end parts of the second conductive member simultaneously by using a plurality of the third region patterns;
a step of joining, by the ohmic contact, the region formed by the first region pattern and the region formed by the second region pattern of each of the first conductive member and the second conductive member; and
a step of joining, by the ohmic contact, the region formed by the second region pattern and the region formed by the third region pattern of each of the first conductive member and the second conductive member, so that a plurality of the peltier elements or the Seebeck elements are formed simultaneously.
